(19) United States
(12) Patent Application Publication
(10) Pub. No.: US 2009/0161809 A1
(43) Pub. Date: Jun. 25, 2009

(54) Method and Apparatus for Variable Frame Rate

(75) Inventors: Liming Xiu, Plano, TX (US); Hongbing Lian, Plano, TX (US); Grady Cook, Plano, TX (US); Christopher Sean Tracy, Frisco, TX (US); Wen Li, Plano, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/337,446

(22) Filed: Dec. 17, 2008

Related U.S. Application Data
(60) Provisional application No. 61/015,438, filed on Dec. 20, 2007.

(51) Int. Cl. H03D 3/24

(52) U.S. Cl. 375/376

(57) ABSTRACT

A method and apparatus for adjusting to a frame rate. The method displays the video frames with varying rates. The method comprising the steps of detecting a change in the frame rate, calculating the FREQ of the frame, adjusting the phase-locked loop utilizing the calculated FREQ, and utilizing the adjusted phase-locked loop output as the pixel clock to display the frame.

### CROSS-REFERENCE TO RELATED APPLICATIONS

This application claims benefit of U.S. provisional patent application Ser. No. 61/015,438, filed Dec. 20, 2007, which is herein incorporated by reference.

### BACKGROUND OF THE INVENTION

1. Field of the Invention

Embodiments of the present invention generally relate to a method and apparatus for efficiently dealing with variable rate among frames.

2. Description of the Related Art

In digital TV broadcasting, the frame rate of the video signal is not constant; rather it varies dependent on the factors, such as, video source. Different video contents are derived from different video sources that bear their own frame rates. For example, when a movie is broadcasted in 720p, it could use 59.94 Hz frame rate. However, during the commercial breaks, the frame rate used for advertisement program might be in 60 Hz. Consequently, in digital TV receiving system, the hardware must be designed to handle this frame rate difference. Hence, frame rate varies between various data stream sources. As a result, when displaying a sequence of images or video, the display apparatus or mechanism has to account for the varying frame rates.

In a digital television display system, the basic element is a pixel. The digital video content is displayed pixel by pixel on the display device. The rate at which the pixels are displayed is controlled by on chip clock generation circuitry (PLL). Traditionally, on chip PLLs are designed only for several commonly used frequencies. In some cases, these frequencies may not satisfy the need for displaying the video content seamlessly, due to the unmatched frame rate from the video source.

To compensate for this problem, in the past, techniques have been used that repeat or drop a video frame in the video stream from time to time. This can make the incoming video rate closely match the displaying video rate. Other techniques exist that modify the length of each video line to diminish the frame rate mismatch. While these methods increase the time interval between frame repeat/drop occurrences, they still allow a visible artifact in the displayed picture.

Additional methods requiring external circuitry to drive the PLL include providing extra crystal and use of an external VCXO. The extra crystal is usually dedicated for specific display frame rates. An external VCXO can be configured to drive the PLL based on the frame buffer fullness/emptiness. The extra crystal and external VCXO solutions are costly.

Therefore, there is a need for an improved method and/or apparatus that deals with the rate difference without causing artifacts.

### SUMMARY OF THE INVENTION

Embodiments of the present invention relate to a method and apparatus for adjusting to a frame rate. The method produces a display of frames with varying rates. The method comprising the steps of detecting a change in the frame rate, calculating the frequency control word FREQ of the frame, adjusting the phase-locked loop utilizing the calculated FREQ, and utilizing the adjusted phase-locked loop to display the frame.

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

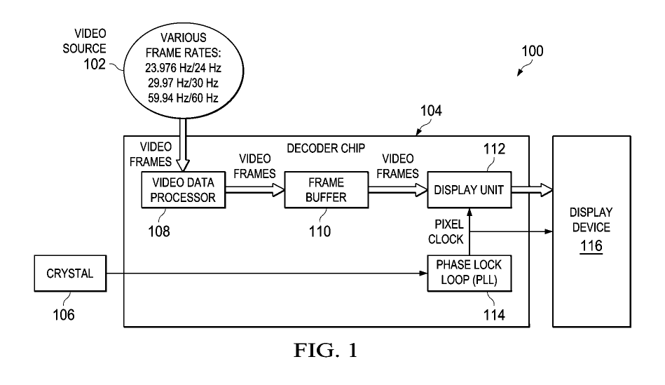

FIG. 1 is an embodiment of a digital video system;

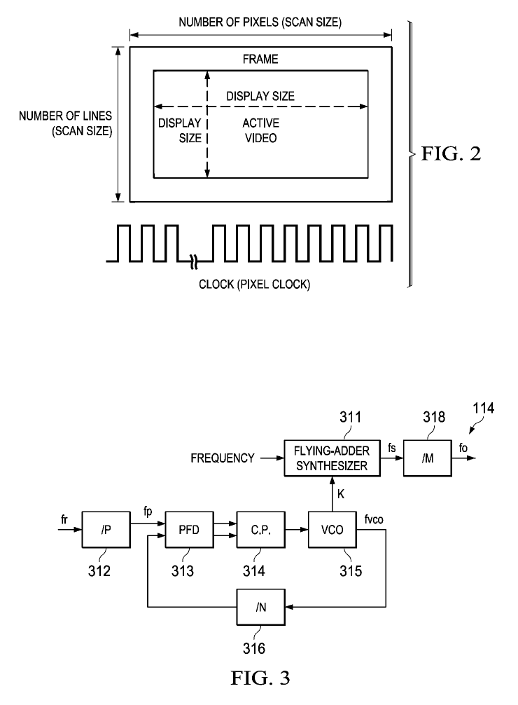

FIG. 2 is an embodiment of a pixel clock and display;

FIG. 3 is an embodiment of a flying-adder phase-locked loop (FAPLL);

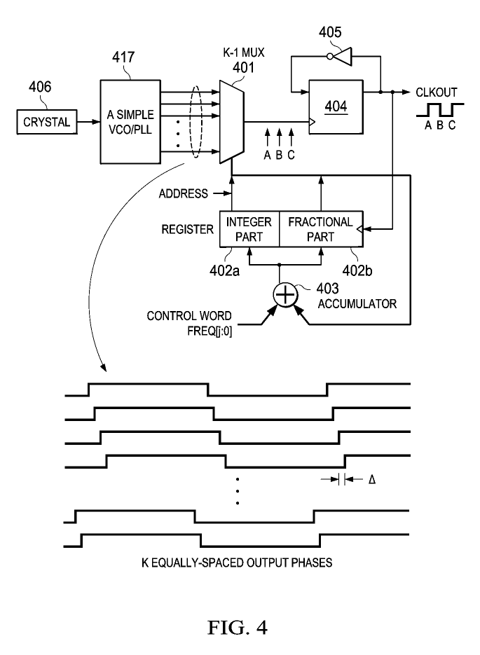

FIG. 4 is an embodiment of a principal of a flying-added phase-locked loop (FAPLL);

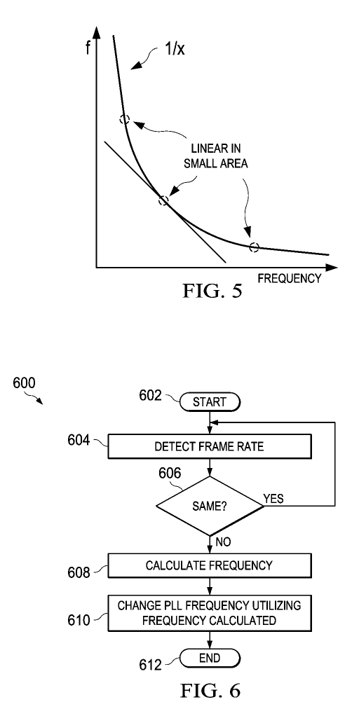

FIG. 5 is an embodiment of a transfer function of fixed-VCO flying-adder phase-locked loop (FAPLL); and

FIG. 6 is an embodiment of a method 600 for adjusting to a frame rate.

### DETAILED DESCRIPTION

For the purposes of this application, a computer readable medium is any medium accessible by a computer for reading, writing, executing, and the like of data and/or instructions.

FIG. 1 is an embodiment of a digital video system 100. More specifically, FIG. 1 is a simplified HDTV video display system. FIG. 1 includes a video source 102, a decoder chip 104, a crystal 106 and a display device 116. The decoder chip 104 includes a video processor 108, a frame buffer 110, a display unit 112 and a phase-locked loop (PLL) 114. The PLL used in the system is Flying-Adder phase-locked PLL. The equation of Flying-Adder Flying-Adder phase-locked PLL can be expressed as:

Tₛ=1/fₛ=FREQ*Δ (1)

Where Tₛ, or fₛ, is the synthesizer's output period or frequency. FREQ is the digital control word. A is the time difference between any two adjacent VCO outputs.

Starting from video source 102, video frames sequentially pass through at least one video data processor 108 inside the decoder chip 104 before being displayed on display device. The video content is processed and displayed frame by frame. Within the decoder chip 104 is the frame buffer 110 between the video processor 108 and the display unit 112 to accommodate the different processing speeds of these systems.

The display unit 112 and the display device 116 are driven by the pixel clock generated from the on-chip PLL 114. In a standard TV system, the digital video content is displayed pixel by pixel on the display device as shown in FIG. 2. FIG. 2 is an embodiment of a pixel clock and display device 116. The rate at which the pixels are displayed is controlled by pixel clock. Its frequency is determined by (2), where F_rate is frame rate, or number of video frames per second. F_size is frame size, which is represented by the number of lines in each frame, or number of video lines per frame (scan size) and L_size is line size, or number of pixels per line (scan size).

fₚᵢₓₑₗ_{_{—}}_{clock}=F_rate*F_size*L_size (2)

FIG. 3 is an embodiment of a flying-adder phase-locked loop (FAPLL) 114 of FIG. 1. Flying-adder PLL 114 includes flying-adder synthesizer 311, divide by P (/P) circuit 312, phase detector (PFD) 313, charge pump (CP) 314, voltage controlled oscillator (VCO) 315, divide by N (/N) circuit 316 and divide by M (/M) circuit 318. /P circuit 312, /N circuit 316 and /M circuit 318 adjust the frequency relationship. For example, /P circuit 312 and /N circuit 316 adjust the frequency relationship between the input frequency fr and the output frequency of VCO 315. These circuits generally enable certain integer ratio N/P between the piezoelectric crystal frequency and the output frequency of VCO 315.

PFD 313 compares the phases of the /P signal and the /N signal and produces an error signal which controls VCO 315. CP 314 generates the control signal for VCO 315 from the phase error signal output from PFD 313. Feedback of the VCO 315 signal fvco enables the phase locked loop to reliably generate an output signal having a stable frequency relationship N/P to the input signal. Flying-adder synthesizer 311 generates an output signal fs that depends both upon the frequency of plural signals K and the value of digital signal FREQ.

As better illustrated in FIG. 4, VCO 315 generates a plurality of signals K preferably equally spaced in phase. It is typical to generate these signals K using a chain of delays. Flying-adder synthesizer 311 receives the FREQ of equation (1). The output signal fs is adjusted by the /M circuit 318 to generate output frequency fo. From the PLL operation equations and equation (1), the FAPLL's output fₒ can be derived as:

f_{vco}=(fᵣ*N)/P,→T_{vco}=P/(fᵣ*N)

Δ=T_{vco}/K=P/(fᵣ*N*K)

fₒ/fᵣ=(N*K)/(FREQ*P*M) (3)

Where fᵣ is the input reference, P is the pre scalar, N is the PLL loop divider, and M is the post divider. K is the number of VCO outputs. The Flying-Adder PLL may be used in two modes: fixed-VCO mode and integer-Flying-Adder mode.

FIG. 4 illustrates the working idea of a flying-adder PLL, such as, used in this invention. The crystal 106, shown in FIG. 1, provides a stable frequency standard for VCO/PLL 417. VCO/PLL 417 embodies /P circuit 312, PFD 313, CP 314, VCO 315 and /N circuit 316 illustrated in FIG. 3. FIG. 4 illustrates VCO/PLL 417 producing K equally spaced output signals having a phase spacing of Δ. These K equally spaces the output signals correspond to plural signals K illustrated in FIG. 3.

These equally spaced output signals supply respective inputs of K to 1 multiplexer 401. The selection made by K to 1 multiplexer 401 is controlled by integer part 402a of register 402. The selected output of K to 1 multiplexer 401 supplies the clock input of flip-flop 404. Each positive going edge of this output toggles flip-flop 404 to an opposite digital output producing a square wave signal CLKOUT having a controlled frequency. Inverter 405 is coupled to flip-flop 404 to retain its state between clock pulses.

Accumulator 403 adds the current contents of register 402 including an integer part stored in integer part 402a and fractional part 402b to the digital control word FREQ of equation 3. If the sum overflows, the most significant bit is discarded. The sum produced by accumulator 403 is stored in register 402 at a time controlled by CLKOUT from flip-flop 404. Each time the sum is loaded into register 402 the number stored in integer part 402a selects an input to K to 1 multiplexer 401. The repeated selection of inputs to K to 1 multiplexer 401 and flip-flop 404 produce the desired clock signal CLKOUT.

Flying-adder synthesizer 311 operates as follows. Suppose the digital value FREQ equals K, the number of inputs to K to 1 multiplexer 401. Then, every addition within accumulator 403 will over flow to the same integral part. Thus, the same input to K to 1 multiplexer 401 will be selected repeatedly. Accordingly, the frequency of CLKOUT will equal the input frequency from VCO/PLL 417 with a phase dependent upon the initial condition of register 402. If the digital value FREQ is larger than K, the input selected will tend to move within K to 1 multiplexer 401 selecting a phase with a longer delay each cycle. This produces a longer pulse period and hence a lower frequency.

If the digital value FREQ is smaller than K, the input selected will tend to move within K to 1 multiplexer 401 selecting a phase with a shorter delay each cycle. This produces a shorter pulse period and, hence, a higher frequency. The fractional part of FREQ provides additional resolution. Assuming the value of FREQ is constant, continual addition of the fractional causes periodic over flow into the integer part. This causes the input of K to 1 multiplexer 401 to dither between two adjacent intervals.

The rate of selection of the two adjacent intervals corresponds to the magnitude of the fractional part. A small fractional part near 0 will most often select the smaller interval and select the larger interval infrequently. A large fractional part near 1 will select the larger interval more often than selecting the smaller interval. A change in the digital value of FREQ will be immediately reflected in the next input of K to 1 multiplexer 401. Thus there is no delay in changing frequencies.

Therefore, the flying-adder synthesizer 311 generates the desired frequency by triggering the toggle-configured D-type Flip-Flip at predetermined time through the selection of different VCO outputs. The output frequency is controlled by a frequency control word FREQ. The equation of Flying-Adder frequency synthesizer is expressed in equation (1).

FIG. 5 is an embodiment of a transfer function of fixed-VCO Flying-Adder PLL. In fixed-VCO mode, the VCO oscillation frequency is fixed with P and N, of FIG. 3 and equation (3), preset to fixed values. Usually, the input reference fᵣ is a known and fixed value. Thus, the output frequency fₒ is dependent on FREQ, when post divider M is also fixed. The frequency transfer function is shown in equation (4), where C=(N*K*fᵣ)/(P*M) is a constant.

fₒ=C/FREQ (4)

In Flying-Adder architecture, FREQ is a real number in the range of 2≦FREQ<2K. Equation (4) shows that, in certain range, virtually any frequency can be obtained since FREQ can have both integer and fraction. In real circuit implementation, FREQ is represented by a register with finite size. For example, in one FAPLL used in a video decoder chip 104, FREQ is a 33-bit register FREQ [32:0], where FREQ [32:27] is the integer part and FREQ [26:0] is the fractional part. For fixed-VCO Flying-Adder, the transfer function of equation (4) can be graphically shown in FIG. 5. The most distinguishing features of fixed-VCO Flying-Adder PLL are the fine frequency resolution, Instantaneous response speed, and Linear transfer function in small range.

Fine frequency resolution: The resolution can be expressed in (5), where p is the number of fractional bits in FREQ. f is the synthesizer's output frequency. δf is the frequency step at this frequency.

δf=−2^{-p}*Δ*f² (5)

Instantaneous response speed: Whenever there is a FREQ updated, the synthesizer's output frequency will be changed in next clock cycle. This is owed to the fact that the VCO is always running at a fixed frequency and the synthesizer circuitry directly modifies the output clock's waveform (period) for generating the desired frequencies.

Linear transfer function in small range: Equation (1) clearly shows that the frequency transfer function of Flying-Adder synthesizer can be described mathematically. In other words, the frequency of the synthesized clock can be precisely predicted when the frequency control word is known. Furthermore, the frequency transfer function can be improved to linear when the control word FREQ varies only in small range. If we define a variable z as z=(FREQ—FREQ₀)/FREQ₀, where FREQ₀ is a fixed value (a center value). Then FREQ can be expressed as FREQ=FREQ₀*(1+z) and from (1):

$$\begin{matrix}f = \frac{1}{Δ * {FREQ}_{0} * ( 1 + z )} \\ = \frac{1}{Δ * {FREQ}_{0}} ( 1 - z + {z}^{2} - {z}^{3} + {z}^{4} - {z}^{5} + … ) \\ \approx \frac{1}{Δ * {FREQ}_{0}} ( 1 - z )\end{matrix} \qquad ( 6 )$$

Thus, in small range |z|<<1, output frequency follows FREQ's change linearly.

FIG. 6 is an embodiment of a method 600 for adjusting to a frame rate. In one embodiment, the method produces a display of frames with varying rates. The method 600 starts at step 602 and proceeds to step 604. At step 604 the method 600 detects a frame rate. At step 606, the method 600 determines if the frame rate is the same as the frame rate of the previous frame. If the frame rate is the same, the method 600 returns to step 602; otherwise, the method 600 proceeds to step 608. At step 608, the method 600 calculates the FREQ of the frame. At step 610, the method 600 adjusts the phase-locked loop utilizing the calculated FREQ, which is utilized to display the frame. The method 600 ends at step 612. Thus, utilizing the method 600, frames with varying frame rates may be displayed without using the methods of adjusting video-line-length, including another crystal, etc.

The advantage of utilizing method 600 include: (1) No need to repeat/drop frames from time to time. (2) No need to modify line length. (3) No need for extra dedicated crystal. (4) No need for external VCXO. In one embodiment, the PLL designed for this application has very fine frequency resolution; hence, it provides for: (1) Accommodate varying frame rates that exist in the industry, with virtually no possibility of frame buffer overflow/underflow. (2) Greatly reduce the software work as well since it eliminates the work needed for handling the line length adjustment, dynamic frame rate changing, screen size adjustment, etc. (3) It is a low cost approach since the new PLL implementation (Flying-Adder PLL) has very minimal hardware overhead. It is virtually “free” since this PLL is needed for other functions in the system as well. (4) It is a low cost approach since it eliminates the extra crystal or external VCXO component.

While the foregoing is directed to embodiments of the present invention, other and further embodiments of the invention may be devised without departing from the basic scope thereof, and the scope thereof is determined by the claims that follow.

What is claimed is:

1. A method for adjusting to a frame rate, wherein the method produces a display of frames with varying rates, the method comprising:
detecting a change in the frame rate;
calculating the FREQ of the frame;
adjusting the phase-locked loop utilizing the calculated FREQ to generate an adjusted phase-loop output; and
utilizing the adjusted phase-locked loop output as the pixel clock to display the frame.

2. A computer readable medium, comprising computer instruction when executed perform a method for adjusting to a frame rate, wherein the method produces a display of frames with varying rates, the method comprising:
detecting a change in the frame rate;
calculating the FREQ of the frame;
adjusting the phase-locked loop utilizing the calculated FREQ to generate an adjusted phase-loop output; and
utilizing the adjusted phase-locked loop output as the pixel clock to display the frame.

3. An apparatus for displaying images, comprising:
means for detecting a change in the frame rate;
means for calculating the FREQ of the frame;
means for adjusting the phase-locked loop utilizing the calculated FREQ to generate an adjusted phase-loop output; and
means for utilizing the adjusted phase-locked loop output as the pixel clock to display the frame.
